(19) United States
(12) Patent Application Publication
(10) Pub. No.: US 2025/0372496 A1
(43) Pub. Date: Dec. 4, 2025

(54) SEMICONDUCTOR DEVICE AND METHOD FOR MANUFACTURING SEMICONDUCTOR DEVICE

(71) Applicant: Mitsubishi Electric Corporation, Tokyo (JP)

(72) Inventor: Koji TANAKA, Tokyo (JP)

(73) Assignee: Mitsubishi Electric Corporation, Tokyo (JP)

(21) Appl. No.: 18/873,591

(22) PCT Filed: Nov. 22, 2022
(86) PCT No.: PCT/JP2022/043190

§ 371 Date: Dec. 10, 2024

(51) Int. Cl. H01L 23/498

(52) U.S. Cl. CPC H01L 23/49838

(57) ABSTRACT

A semiconductor device according to the present disclosure includes a semiconductor chip, a metal block having a first surface and a second surface opposite to the first surface, the first surface being bonded to the semiconductor chip with a bonding material, and a lead electrode bonded to the second surface of the metal block, wherein a plurality of irregularities are formed on a surface of the lead electrode opposite to a surface thereof bonded to the metal block.

### FIELD

The present disclosure relates to a semiconductor device and a method for manufacturing the semiconductor device.

### BACKGROUND

Patent Document 1 discloses a structure in which a pad portion and a conductive spacer are bonded in a semiconductor device. The bonding of the pad portion and the spacer is performed by, for example, ultrasonic bonding.

### CITATION LIST

### Patent Literature

[PTL 1] WO 2020/105476

### SUMMARY

### Technical Problem

In a semiconductor device such as a power semiconductor device, a semiconductor chip and a wiring member such as a lead electrode may be bonded. As a method of bonding the lead electrode and the semiconductor chip, for example, there is a method of discharging a molten metal to one main surface of the semiconductor chip. There is also a method of arranging a bonding material and lead electrodes on a semiconductor chip bonded in advance to a circuit pattern on an insulating substrate and reflowing. In such a method of bonding the lead electrode and the semiconductor chip, the bonding area is larger than that in a method of forming a circuit by bonding a metal wire and a semiconductor chip. Therefore, a large current and a long life can be expected.

However, in the above method, it is necessary to heat the entire semiconductor device in the step of bonding the lead electrode and the upper surface of the semiconductor chip. Therefore, the bonding material of the bonding portion between the semiconductor chip and the insulating substrate which are bonded in advance may be remelted. At this time, it may be necessary to re-inspect the bonding portion on the rear surface of the semiconductor chip. Further, when solder is used as a bonding material between the rear surface of the semiconductor chip and the insulating substrate, there is a problem that the rear surface electrode of the semiconductor chip diffuses into the solder, and the bonding strength is reduced.

On the other hand, in order to avoid the above-described problem, it is considered that the semiconductor chip and the lead electrode are bonded by applying ultrasonic vibration, that is, ultrasonic bonding is performed. However, when the upper surface of the semiconductor chip is used as a bonding target portion of the ultrasonic bonding, the semiconductor chip may be damaged, and thus there was a problem in that ultrasonic bonding could not be applied.

An object of the present disclosure is to provide a semiconductor device and a method for manufacturing the semiconductor device that can suppress damage to a semiconductor chip during ultrasonic bonding.

### Solution to Problem

A semiconductor device according to the present disclosure includes a semiconductor chip; a metal block having a first surface and a second surface opposite to the first surface, the first surface being bonded to the semiconductor chip with a bonding material; and a lead electrode bonded to the second surface of the metal block; wherein a plurality of irregularities are formed on a surface of the lead electrode opposite to a surface thereof bonded to the metal block.

A method for manufacturing a semiconductor device according to the present disclosure includes after bonding a semiconductor chip to a first surface of a metal block having the first surface and a second surface opposite to the first surface with a bonding material, applying ultrasonic vibration from a surface of a lead electrode opposite to the metal block to ultrasonically bond the second surface of the metal block to the lead electrode.

### Advantageous Effects of Invention

In the semiconductor device and the method for manufacturing the semiconductor device according to the present disclosure, the metal block and the lead electrode are ultrasonically bonded to each other, and thus it is possible to suppress damage to the semiconductor chip during the ultrasonic bonding.

### BRIEF DESCRIPTION OF DRAWINGS

FIG. 1 is a cross-sectional view of a semiconductor device according to a first embodiment.

FIG. 2 is a plan view of the semiconductor device according to the first embodiment.

FIG. 3 is a view for explaining another example of ultrasonic bonding marks.

FIG. 4 is a cross-sectional view of a semiconductor device according to a second embodiment.

FIG. 5 is a cross-sectional view of a semiconductor device according to a third embodiment.

FIG. 6 is a cross-sectional view of a semiconductor device according to a fourth embodiment.

FIG. 7 is a cross-sectional view of a semiconductor device according to a fifth embodiment.

### DESCRIPTION OF EMBODIMENTS

A semiconductor device and a method for manufacturing a semiconductor device according to each embodiment are described with reference to drawings. Identical or corresponding constitutional elements are given the same reference numerals, and the repeated description of such constitutional elements may be omitted.

### First Embodiment

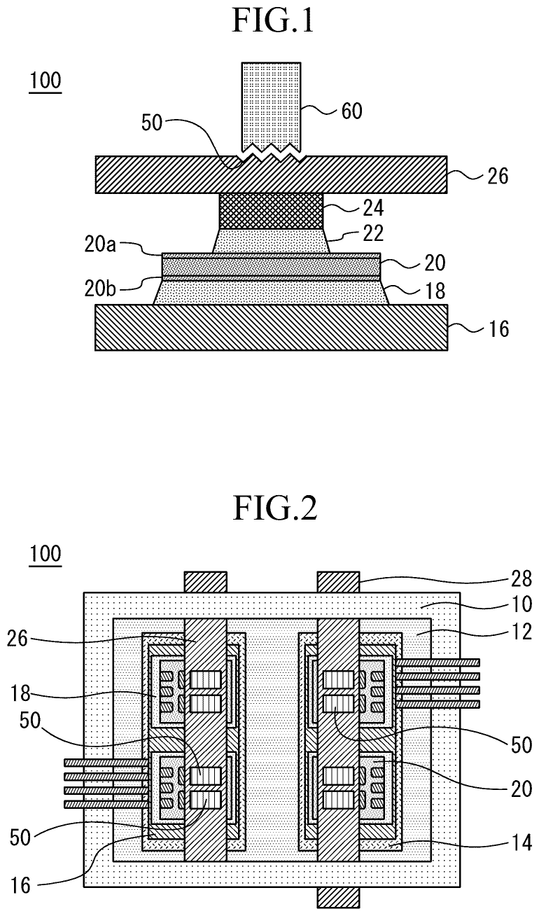

FIG. 1 is a cross-sectional view of a semiconductor device 100 according to the first embodiment. FIG. 2 is a plan view of the semiconductor device 100 according to the first embodiment. FIG. 1 shows a configuration of a typical bonding portion of the semiconductor chip 20, the metal block 24, and the lead electrode in the semiconductor device 100. In FIG. 1, the semiconductor device 100 is illustrated in a simplified manner, and for example, wires, signal terminals, and the like, which are signal lines electrically connected to the semiconductor chip 20, are omitted.

The semiconductor device 100 is, for example, a power semiconductor device. In the semiconductor device 100, a case 10 is provided on a base plate 12. The base plate 12 is formed of a material having excellent thermal conductivity such as an aluminum alloy or copper. An insulating substrate 14 is bonded to a region of the upper surface of the base plate 12 surrounded by the case 10 by a bonding material such as solder or soft solder. The insulating substrate 14 includes an insulating layer formed of a ceramic having excellent thermal conductivity such as aluminum nitride or silicon nitride or resin, and circuit patterns 16 provided on both surfaces of the insulating layer. The circuit pattern 16 is formed of an aluminum alloy, copper, or the like. FIG. 1 shows the circuit pattern 16 provided on the upper surface of the insulating layer of the insulating substrate 14.

The semiconductor chip 20 has a substrate, an electrode 20a provided on the upper surface of the substrate, and an electrode 20b provided on the rear surface of the substrate. The electrode 20b of the semiconductor chip 20 is bonded to the circuit pattern 16 by using a bonding material 18. The bonding material 18 is, for example, solder, soft solder, or the like. The semiconductor chip 20 is, for example, an IGBT, a diode, a reverse conducting IGBT, or the like made of a silicon (Si) material. The semiconductor chip 20 may be a MOSFET, a Schottky diode, or the like formed of a material having a larger band gap than Si, such as silicon carbide (SiC) or gallium nitride (GaN). The number of semiconductor chips 20 on the insulating substrate 14 is not limited. A required number or type of semiconductor chips 20 may be mounted according to the use of the semiconductor device 100.

The metal block 24 has a first surface and a second surface opposite to the first surface. The first surface is bonded to the electrode 20a of the semiconductor chip 20 with a bonding material 22. The bonding material 22 is solder, soft solder, or the like. The metal block 24 is formed of a metal having excellent thermal conductivity and low electric resistance, such as copper or aluminum. The metal block 24 is not limited to this, and may be any metal having desired characteristics.

The lower surface of the lead electrode 26 formed of metal is bonded to the second surface of the metal block 24. The bonding between the lead electrode 26 and the metal block 24 is ultrasonic bonding. The metal block 24 and the lead electrode 26 are bonded to each other without a bonding material. A plurality of irregularities 50 are formed on a surface of the lead electrode 26 opposite to the surface bonded to the metal block 24. The plurality of irregularities 50 are ultrasonic bonding marks. The plurality of irregularities 50 are formed at a position of the lead electrode 26 overlapping the metal block 24 in a plan view.

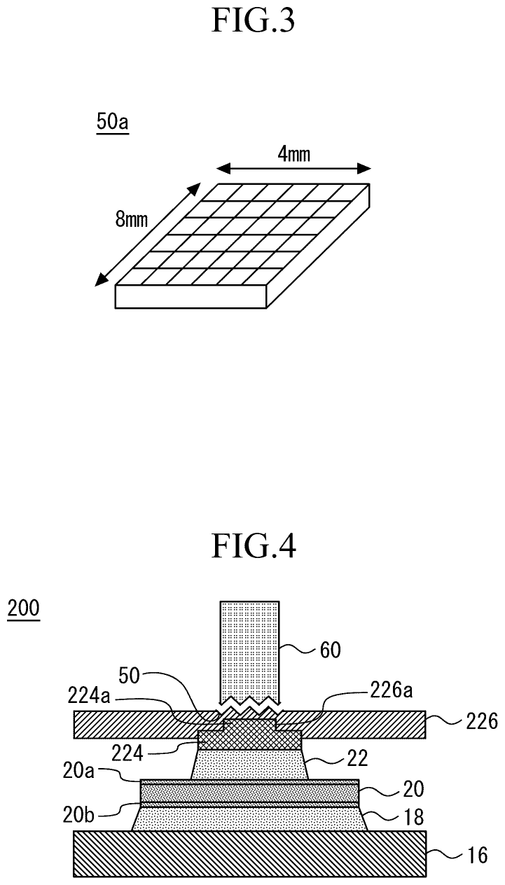

The ultrasonic bonding mark is also called an ultrasonic vibration application mark. The shape of the plurality of irregularities 50, which are ultrasonic bonding marks, varies depending on the tip shape and the vibration direction of the ultrasonic vibration tool 60. For example, by applying a unidirectional reciprocating vibration to the upper surface of the lead electrode 26, as shown in FIG. 2, an application mark in which parallel irregularities are continuous can be formed as the plurality of irregularities 50. Further, depending on the shape of the tip of the ultrasonic vibration tool 60, a plurality of quadrangular pyramids may be continuously formed as the plurality of irregularities 50. FIG. 3 is a view for explaining another example of the ultrasonic bonding marks. In the example of FIG. 3, the plurality of irregularities 50a are arranged in two directions. The plurality of irregularities 50a are formed in a range of 4 mm×8 mm, for example. The width of each projection included in the plurality of irregularity 50a is, for example, about 0. 1 mm to 10 mm.

A plurality of metal blocks 24 may be bonded to one semiconductor chip 20. The ultrasonic bonding marks are formed in a number corresponding to the number of the metal blocks 24. In the example of FIG. 2, two metal blocks 24 are bonded to one semiconductor chip 20.

The lead electrode 26 may be formed by extending an external electrode 28, which is inserted into the case 10 in advance, onto the semiconductor chip 20. The lead electrode 26 may be bonded to an external electrode 28 provided in advance in the case 10 by solder bonding, laser welding, ultrasonic bonding, or the like. Further, a part of the lead electrodes 26 may be connected to the circuit pattern 16 by ultrasonic bonding, solder bonding, laser welding, or the like to form a circuit. Further, one lead electrode 26 may be bonded across a plurality of metal blocks 24 on a plurality of semiconductor chips 20.

Next, the procedure for assembling the semiconductor device 100 according to the present embodiment will be described below. First, the circuit pattern 16 of the insulating substrate 14 and the semiconductor chip 20, and the semiconductor chip 20 and the first surface of the metal block 24 are bonded by the bonding materials 18 and 22 such as plate solder, solder paste, and soft solder. In the bonding step, first, the bonding materials 18 and 22 are mounted on the circuit pattern 16 and the semiconductor chip 20. Generally, solder is often used for the bonding materials 18 and 22. The solder paste or the like as the bonding materials 18 and 22 may be mounted by screen printing or may be applied by using a dispenser or the like. Next, the semiconductor device 100 is heated to a temperature exceeding the melting point of the bonding materials 18 and 22, thereby performing bonding.

The metal block 24 and the semiconductor chip 20 may be bonded simultaneously in the process of bonding the semiconductor chip 20 to the circuit pattern 16. Alternatively, the semiconductor chip 20 may be bonded to the circuit pattern 16, and then the semiconductor chip 20 may be bonded to the metal block 24. In this case, the bonding material 22 may be disposed on the semiconductor chip 20 by screen printing, dispensing, or the like, the metal block 24 may be disposed on the bonding material 22, and then the bonding material 22 may be locally heated by laser heating, hot air heating, or the like to be bonded. This can suppress the bonding material 18 from being melted again.

Next, the case 10 is bonded to the base plate 12. In this step, first, a silicone-based or epoxy-based adhesive is applied to the bonding surface of the case 10 to be bonded to the base plate 12. Thereafter, the base plate 12 to which the semiconductor chip 20 and the insulating substrate 14 are bonded is fitted to the case 10, and a load is applied to the case 10 to bring the case 10 and the base plate 12 into close contact with each other. The case 10 and the base plate 12 may be fastened to each other by a tapping screw or the like. The adhesive may be heated and solidified in a state where the case 10 and the base plate 12 are fixed by a clamp jig or the like.

Next, the lead electrode 26 is disposed on the second surface of the metal block 24. Next, as shown in FIG. 1, ultrasonic vibration is applied from the surface of the lead electrode 26 on the opposite side to the metal block 24, and the second surface of the metal block 24 and the lead electrode 26 are ultrasonically bonded. The lead electrode 26 is pressurized by an ultrasonic vibration tool 60 from the surface opposite to the surface in contact with the metal block 24. The lead electrode 26 and the metal block 24 are bonded by applying ultrasonic vibration while applying pressure with a constant load.

Next, in order to form a signal circuit for controlling the semiconductor chip 20, the control electrode on the semiconductor chip 20 and the external signal terminals are connected by wire using ultrasonic bonding. In general, aluminum or the like having high thermal conductivity and high electrical conductivity is often used for the wire.

Next, the inside of the case 10 is sealed with a sealing resin. As the sealing resin, a silicone gel or an epoxy resin is often used. The sealing resin is not limited to these, and any resin can be used as long as it has desired physical properties such as elastic modulus, heat resistance, adhesiveness, and linear expansion coefficient. Next, the semiconductor device 100 is placed in a curing furnace or the like to cure the sealing resin, and the required curing is performed to complete the shape of the semiconductor device 100. Thereafter, the semiconductor device 100 is completed by performing inspection of electrical characteristics and the like.

In the present embodiment, the metal block 24 is provided between the semiconductor chip 20 and the lead electrode 26. By ultrasonically bonding the metal block 24 and the lead electrode 26, damage to the semiconductor chip 20 during ultrasonic bonding can be suppressed. That is, since the upper surface of the semiconductor chip 20 does not become a bonding portion of the ultrasonic bonding, even when the ultrasonic vibration is applied while the lead electrode 26 is pressurized, it is possible to suppress damage to the semiconductor chip 20. As a result, in the present embodiment, ultrasonic bonding can be applied when forming a circuit between the lead electrode 26 and the semiconductor chip 20, and it is not necessary to heat the entire semiconductor device 100. Therefore, the bonding portion between the semiconductor chip 20 and the insulating substrate 14, which are bonded in advance, can be prevented from being remelted. Therefore, re-inspection of the bonding portion on the rear surface of the semiconductor chip 20 can be avoided, and the semiconductor device 100 can be manufactured at low cost. Further, the bonding strength of the rear surface of the semiconductor chip 20 can be prevented from being lowered.

As described above, the semiconductor chip 20 may be made with a wide bandgap semiconductor. The wide bandgap semiconductor is, for example, silicon carbide, a gallium-nitride-based material, or diamond. According to the present embodiment, even when the semiconductor chip 20 is formed of a wide bandgap semiconductor and a high current flows, a decrease in the bonding strength can be suppressed, and a decrease in the reliability of the semiconductor device 100 can be suppressed.

The above-described modifications can be appropriately applied to semiconductor devices and methods for manufacturing semiconductor devices according to the following embodiments. Note that the semiconductor devices and the methods for manufacturing the semiconductor devices according to the following embodiments have many common points with the first embodiment, and thus the description will be made mainly on the differences from the first embodiment.

### Second Embodiment

FIG. 4 is a cross-sectional view of a semiconductor device 200 according to the second embodiment. The semiconductor device 200 is different from the semiconductor device 100 of the first embodiment in the structures of the metal block 224 and the lead electrode 226. The other configuration is the same as that of the first embodiment. A fitting portion to be fitted to the lead electrode 226 is formed on the second surface of the metal block 224. In particular, a convex portion 224a is formed on the second surface of the metal block 224, and a concave portion 226a is formed on the lower surface of the lead electrode 226. The metal block 224 and the lead electrode 226 are ultrasonically bonded in a state where the convex portion 224a of the metal block 224 enters the concave portion 226a of the lead electrode 226. Thus, the flat portion of the upper surface of the convex portion 224a of the metal block 224 and the flat bottom portion of the concave portion 226a of the lead electrode 226 are ultrasonically bonded.

In the present embodiment, the metal block 224 and the lead electrode 226 are fitted to each other, and thus even when the lead electrode 226 is not fixed before bonding, the lead electrode 226 can be easily positioned in the horizontal direction. Further, the positioning accuracy of the lead electrode 226 in the horizontal direction can be improved, and the semiconductor device 200 can be stably manufactured.

The shapes of the convex portion 224a and the concave portion 226a are not limited as long as the metal block 224 and the lead electrode 226 can be fitted to each other. Alternatively, a concave portion may be formed in the metal block 224, and a convex portion may be formed in the lead electrode 226.

### Third Embodiment

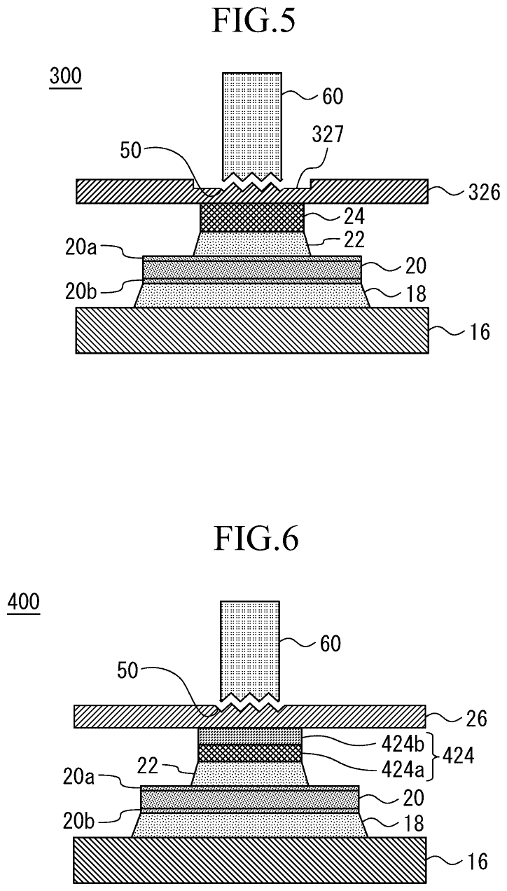

FIG. 5 is a cross-sectional view of a semiconductor device 300 according to the third embodiment. The semiconductor device 300 is different from the semiconductor device 100 of the first embodiment in the structure of the lead electrode 326. The other configuration is the same as that of the first embodiment. A recess 327 is formed on a surface of the lead electrode 326 opposite to the surface bonded to the metal block 24. The plurality of irregularities 50 which are ultrasonic bonding marks are formed on the bottom surface of the recess 327.

In the present embodiment, the recess 327 is formed on the upper surface of the lead electrode 326, and thus scattering of metal debris generated when the lead electrode 26 and the metal block 24 are ultrasonically bonded can be suppressed. Therefore, the semiconductor device 300 can be stably manufactured. The depth of the recess 327 is preferably larger than the maximum depth of the plurality of irregularities 50. This can enhance the effect of suppressing scattering of metal debris. The maximum depth of the plurality of irregularities 50 is, for example, 0.5 mm to 0.8 mm.

The width of the recess 327 may be larger than the width of the region of the lead electrode 326 in contact with the metal block 24. The area of the recess 327 may be larger than the area of the region of the lead electrode 326 in contact with the metal block 24. Thus, even when the recess 327 is formed, the area of the ultrasonic bonding portion can be sufficiently secured.

### Fourth Embodiment

FIG. 6 is a cross-sectional view of a semiconductor device 400 according to the fourth embodiment. The semiconductor device 400 is different from the semiconductor device 100 of the first embodiment in the structure of the metal block 424. The other configuration is the same as that of the first embodiment. The metal block 424 includes a Cu layer 424a bonded to the semiconductor chip 20 with the bonding material 22 and an Al layer 424b bonded to the lead electrode 26 by ultrasonic bonding. The metal block 424 is a clad material formed by, for example, rolling and joining a copper material and an aluminum material by applying pressure to the surfaces thereof.

In the present embodiment, the soft aluminum layer 424b is provided in a part of the metal block 424, and thus, when the lead electrode 26 and the metal block 424 are bonded to each other by ultrasonic bonding, damage to the semiconductor chip 20 caused by ultrasonic vibration can be reduced. On the other hand, the aluminum material is unlikely to generate an intermetallic compound with the bonding material 22 such as solder. The presence of the Cu layer 424a on the surface bonded to the semiconductor chip 20 with the bonding material 22 facilitates bonding of the semiconductor chip 20 to the block 424. Therefore, the semiconductor device 400 can be stably manufactured. The metal block 424 may include the Cu layer 424a and the Al layer 424b. For example, another metallic layer may be provided between the Cu layer 424a and the Al layer 424b.

### Fifth Embodiment

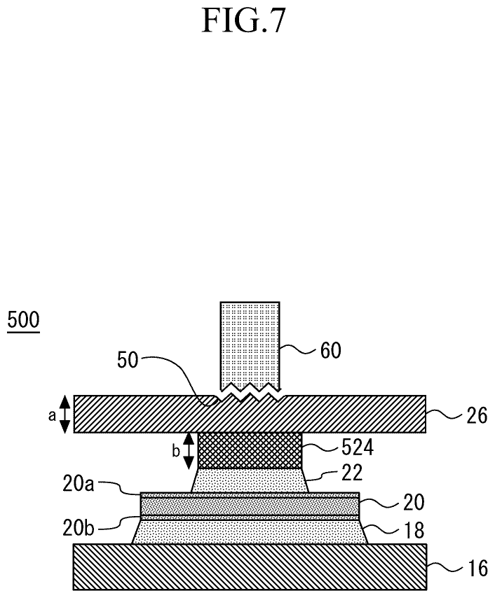

FIG. 7 is a cross-sectional view of a semiconductor device 500 according to the fourth embodiment. The thickness b of the metal block 524 of the semiconductor device 500 is equal to or greater than the thickness of the portion of the lead electrode 26 that is bonded to the metal block 524. The other configuration is the same as that of the first embodiment. For example, when the lead electrode 26 are 0.6 mm thick, the metal block 524 is 0.6 mm thick or thicker. In the present embodiment, in the step of ultrasonically bonding the lead electrode 26 and the metal block 524, the metal block 524 thicker than the lead electrode 26 is present between the semiconductor chip 20 and the lead electrode 26. This makes it possible to further suppress damage to the semiconductor chip 20 when ultrasonic vibration is applied to the lead electrode 26 while applying pressure to the lead electrode 26. Therefore, the semiconductor device 500 can be stably manufactured.

The technical features described in the embodiments may be used in appropriate combination.

### REFERENCE SIGNS LIST

10 case, 12 base plate, 14 insulating substrate, 16 circuit pattern, 18 bonding material, 20 semiconductor chip, 20a, 20b electrode, 22 bonding material, 24 metal block, 26 lead electrode, 28 external electrode, 50, 50a irregularities, 60 ultrasonic vibration tool, 100, 200 semiconductor device, 224 metal block, 224a convex portion, 226 lead electrode, 226a concave portion, 300 semiconductor device, 326 lead electrode, 327 recess, 400 semiconductor device, 424 metal block, 424a copper layer, 424b aluminum layer, 500 semiconductor device, 524 metal block

1. A semiconductor device comprising:
a semiconductor chip;
a metal block having a first surface and a second surface opposite to the first surface, the first surface being bonded to the semiconductor chip with a bonding material; and
a lead electrode bonded to the second surface of the metal block; wherein
a plurality of irregularities are formed on a surface of the lead electrode opposite to a surface thereof bonded to the metal block.

2. The semiconductor device according to claim 1, wherein the plurality of irregularities are ultrasonic bonding marks.

3. The semiconductor device according to claim 1, wherein the metal block and the lead electrode are bonded to each other without a bonding material.

4. The semiconductor device according to claim 1, wherein a fitting portion to be fitted to the lead electrode is formed on the second surface of the metal block.

5. The semiconductor device according to claim 1, wherein
a recess is formed in the surface of the lead electrode opposite to the surface thereof bonded to the metal block, and
the plurality of irregularities are formed on a bottom surface of the recess.

6. The semiconductor device according to claim 5, wherein a width of the recess is larger than a width of a region of the lead electrode which is in contact with the metal block.

7. The semiconductor device according to claim 5, wherein a depth of the recess is larger than a maximum depth of the plurality of irregularities.

8. The semiconductor device according to claim 1, wherein the metal block includes an aluminum layer bonded to the lead electrode and a copper layer bonded to the semiconductor chip.

9. The semiconductor device according to claim 1, wherein a thickness of the metal block is equal to or larger than a thickness of a portion of the lead electrode bonded to the metal block.

10. The semiconductor device according to claim 1, wherein the semiconductor chip is made with a wide bandgap semiconductor.

11. The semiconductor device according to claim 10, wherein the wide bandgap semiconductor is silicon carbide, gallium-nitride-based material or diamond.

12. A method for manufacturing a semiconductor device, the method comprising:
after bonding a semiconductor chip to a first surface of a metal block having the first surface and a second surface opposite to the first surface with a bonding material, applying ultrasonic vibration from a surface of a lead electrode opposite to the metal block to ultrasonically bond the second surface of the metal block to the lead electrode.
